(19) United States
(12) Patent Application Publication
(10) Pub. No.: US 2019/0059163 A1
(43) Pub. Date: Feb. 21, 2019

(54) A METHOD OF THERMAL DECOUPLING OF PRINTED CIRCUITS AND A PRINTED CIRCUIT FOR USE THEREIN

(71) Applicant: OSRAM GmbH, Munich (DE)

(72) Inventors: Thomas Rieger, Aufhausen (DE); Davide Grosso, Ponzano Veneto (IT); Franco Zanon, Cassola (IT)

(21) Appl. No.: 15/761,453

(22) PCT Filed: Sep. 19, 2016
(86) PCT No.: PCT/IB2016/055574

§ 371 Date: Mar. 20, 2018

(30) Foreign Application Priority Data
Sep. 24, 2015 (IT) 102015000054991

(51) Int. Cl. H05K 3/40; H05K 1/02; H05K 1/11; H05K 1/18; H05K 3/22; F21V 29/10

(52) U.S. Cl. CPC H05K 3/4007; H05K 1/0201; H05K 1/111; H05K 1/181; H05K 3/22; F21V 19/0015; H05K 2201/10106; H05K 2201/09227; H05K 2201/062; H05K 2201/09381; F21V 29/10

(57) ABSTRACT

In order to counter heat propagation between adjacent sections of a ribbon-like printed circuit board, the sections being individually exposed to heat between opposed border lines, with printed circuit board including an electrically insulating substrate with electrically conductive pads for mounting components thereon, the adjacent sections are terminated at the opposed border lines with at least one electrically conductive borderline pad, which has a separation gap to the border line, and/or is coupled to an electrically conductive line extending on substrate between a first end at borderline pad and a second end away from borderline pad. The first end and the second end may be located at a first and at a second distances to border line, the second distance being longer than the first distance, and/or the electrically conductive line may have a narrower cross section than the first and the second ends.

### CROSS-REFERENCE TO RELATED APPLICATION

The present application is a national stage entry according to 35 U.S.C. §371 of PCT application No.: PCT/IB2016/055574 filed on Sep. 19, 2016, which claims priority from Italian Patent Application Serial No.: 102015000054991 which was filed Sep. 24, 2015, and is incorporated herein by reference in its entirety.

### TECHNICAL FIELD

The description relates to printed circuits.

One or more embodiments may find employment e.g. in reel-to-reel manufacturing processes, which may be applied e.g. to flexible printed circuits.

### BACKGROUND

So called reel-to-reel processes may be used for mounting, e.g. via an SMT technology, semiconductor devices (such as electrically-powered solid-state light radiation sources, e.g. LED sources) onto printed circuits such as Flexible Printed Circuits (FPCs).

Such an assembling technique may be advantageous for the manufacturing process, e.g. thanks to the reduction of substrate handling operations and/or thanks to the already present electrical/mechanical connection of the individual working units, in the form of a continuous product of an indefinite length which may be cut to measure according to the application and use requirements.

Further advantages may be derived from the possibility of using, instead of a continuous advancement of the ribbon or foil, a stop-and-go step advancement regulated according to the performance of other operations, such as solder paste application, SMT component pick and place, soldering, testing, foil or ribbon cutting.

In such a context aspects may arise as regards thermal management, especially as regards the thermal decoupling of the part or section of the foil or ribbon which is exposed to heat (so-called Heated Area, HA), e.g. during soldering, with respect to the preceding adjacent part or section (which e.g. is already soldered) and the following adjacent part or section (which e.g. is still to be soldered).

It may be desirable that heating may be limited to the sole section which currently needs heating, while avoiding the undesirable heat propagation towards neighbouring sections.

### SUMMARY

One or more embodiments aim at providing a thermal decoupling solution which may be used in the previously outlined context.

According to one or more embodiments, said object may be achieved thanks to a method having the features set forth in the claims that follow.

One or more embodiments may also concern a corresponding printed circuit, specifically a corresponding Printed Circuit Board (PCB).

One or more embodiments may offer one or more of the following advantages:
possibility of achieving a suitable degree of thermal decoupling, without the need of modifying the manufacturing equipment,
adaptability to a wide range of PC designs (e.g. Flexible Printed Circuits, FPCs),
possibility of applying the solution to a wide range of PC constructions, e.g. FPCs, and to different base materials.

### BRIEF DESCRIPTION OF THE DRAWINGS

In the drawings, like reference characters generally refer to the same parts throughout the different views. The drawings are not necessarily to scale, emphasis instead generally being placed upon illustrating the principles of the disclosed embodiments. In the following description, various embodiments described with reference to the following drawings in which:

FIG. 1, comprising two parts respectively denoted as a) and b), generally exemplifies a process involving heat, adapted to be performed on printed circuits,

FIG. 2 exemplifies one or more embodiments,

FIG. 3 is a view in an enlarged scale of the portion of FIG. 2 denoted by arrow III, and

FIGS. 4 and 5 exemplify a possible aspect of one or more embodiments.

### DETAILED DESCRIPTION

In the following description, numerous specific details are given to provide a thorough understanding of various embodiments.

One or more embodiments may be practiced without one or more of the specific details, or with other methods, components, materials, etc. In other instances, well-known structures, materials, or operations are not shown or described in detail to avoid obscuring various aspects of the embodiments. Reference throughout this specification to “one embodiment” or “an embodiment” means that a particular feature, structure, or characteristic described in connection with the embodiment is included in at least one embodiment. Thus, the possible appearances of the phrases “in one embodiment” or “in an embodiment” in various places throughout this specification are not necessarily all referring to the same embodiment. Furthermore, particular features, structures, or characteristics may be combined in any suitable manner in one or more embodiments.

The headings provided herein are for convenience only, and therefore do not interpret the extent of protection or the scope of the embodiments.

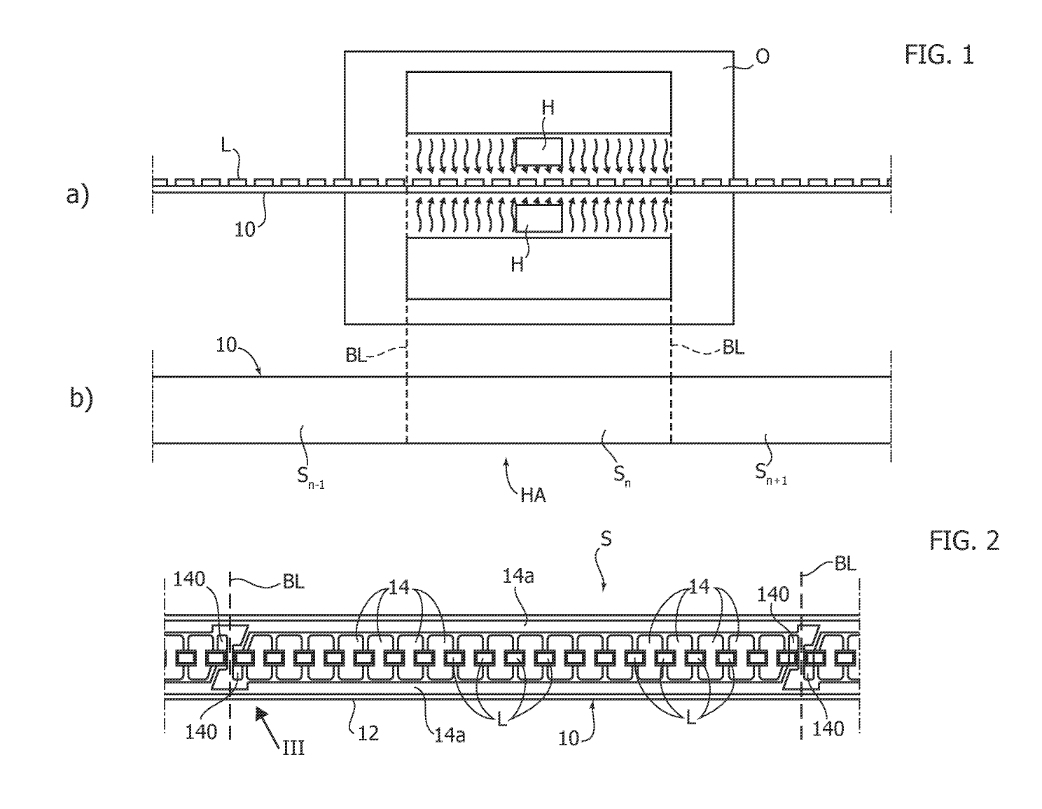

Part a) of FIG. 1 schematically exemplifies a process, such as a so-called “reel-to-reel” process, which performs a heat treatment on a printed circuit 10, e.g. in a processing station (“oven”) denoted as 0.

For example, part a) of FIG. 1 may be seen as an ideal side elevation view, partially in cross section, of a processing station O wherein electronic components L, such as electrically powered light radiation sources, e.g. LED sources, are soldered on a printed circuit 10, theoretically of indefinite length.

For example, the processing performed in station O may be a heat treatment, which melts the solder paste in order to bring about the mechanical and electrical connection of components L to printed circuit 10.

According to criteria known in themselves, printed circuit (or, more correctly, Printed Circuit Board, PCB) 10 may include a substrate 12 of an electrically (and thermally) insulating material, such as polyimide, PI, whereon pads 14 are formed of an electrically (and thermally) conductive material for mounting light radiation sources L and/or other electrical/electronic components (e.g. integrated drivers for sources L), components L being arranged e.g. bridge-like between pads 14.

In addition to pads 14, which are e.g. distributed in a regular array of substantially equally-spaced pads, there may be provided further electrically conductive lines, such as one or more lines 14a adapted to extend along either side or both sides of printed circuit 10, e.g. as the anode and cathode power lines of pads 14.

Of course, these features are shown here by way of example only: as a matter of fact, one or more embodiments may apply to printed circuits having completely different designs.

In one or more embodiments, printed circuit 10 may be generally ribbon-like.

In one or more embodiments, printed circuit 10 may be a Flexible Printed Circuit (FPC).

In one or more embodiments, as exemplified in FIG. 1, printed circuit 10 is adapted to advance through heat treatment station O according to a typical reel-to-reel process, e.g. from left to right with respect to the viewpoint of FIG. 1.

Part b) of FIG. 1 may be seen as an ideal top view of circuit 10, highlighting that, e.g. in the case of a stop-and-go step advancing, a certain portion or section Sn of printed circuit 10 is exposed to the heat of heat sources H of station O within a heated area HA ideally delimited by two border lines BL, respectively arranged upstream and downstream heated area HA in the advancing direction of circuit 10 through station O.

In this situation, the need is felt to limit the heating action as much as possible to section Sn, which is currently individually exposed to heat sources H, while reducing the heat propagation to the adjacent sections which are respectively denoted as Sₙ₋₁ and Sₙ₊₁.

In the presently considered example, sections Sₙ₋₁ and Sₙ₊₁ represent portions of the printed circuits which are still to be heat-treated (e.g. section Sₙ₋₁) or have already been heat-treated (e.g. section Sₙ₊₁).

Specifically, sections Sₙ₋₁ and Sₙ₊₁ adjacent section Sn which is currently being treated should be kept at a lower temperature than heated area HA hosting section Sₙ which is currently being treated.

For example, for a still-to-be-soldered section Sₙ₋₁, the solder mass must not undergo a change of features (e.g. due to component evaporation, chemical reactions, thermal changes etc.) which may jeopardize the soldering process when said section enters processing station O.

Such considerations apply to some extent also to already soldered section Sₙ₊₁: in both sections Sₙ₋₁ and Sₙ₊₁, as a matter of fact, neither the base material of printed circuit 10 or the components L arranged thereon (either soldered or unsoldered) should be damaged through an excessive repeated exposure to heat.

One or more embodiments may provide a thermal decoupling between adjacent portions . . . , Sₙ₋₁, Sₙ, Sₙ₊₁, . . . of printed circuit 10, which must be individually heat treated one after the other in station O, by a modification of the features of printed circuit 10 itself.

One or more embodiments may be based on the fact that heat propagation through a metal conductor, e.g. copper, may be modelled as:

Q′=λ(ΔT. S)/L

wherein:
Q′ is the quantity of heat transferred (by conduction) per time unit,
λ is the thermal conduction constant of the material (e.g. metal, such as copper),
ΔT is the temperature difference between both ends of the related conductor (thermal path),
S is the cross section surface of said thermal path, and
L is the length of said thermal path.

One or more embodiments may therefore envisage the implementation, at border lines BL between adjacent sections . . . Sₙ₋₁, Sₙ, Sₙ₊₁, . . . , of one or more provisions adapted to include e.g. a separation between adjacent paths, an elongation of possible heat conduction paths and/or a section narrowing of said paths, through which heat transfer may take place due to the thermal coupling between adjacent sections . . . Sₙ₋₁, Sₙ, Sₙ₊₁, . . . of printed circuit 10.

Moreover, the structure of printed circuit 10 has an electrically (and thermally) non-conductive substrate 12, on which there are applied lines 14, 14a of electrically conductive material (e.g. a metal such as copper) so that they are not only electrically but thermally conductive as well.

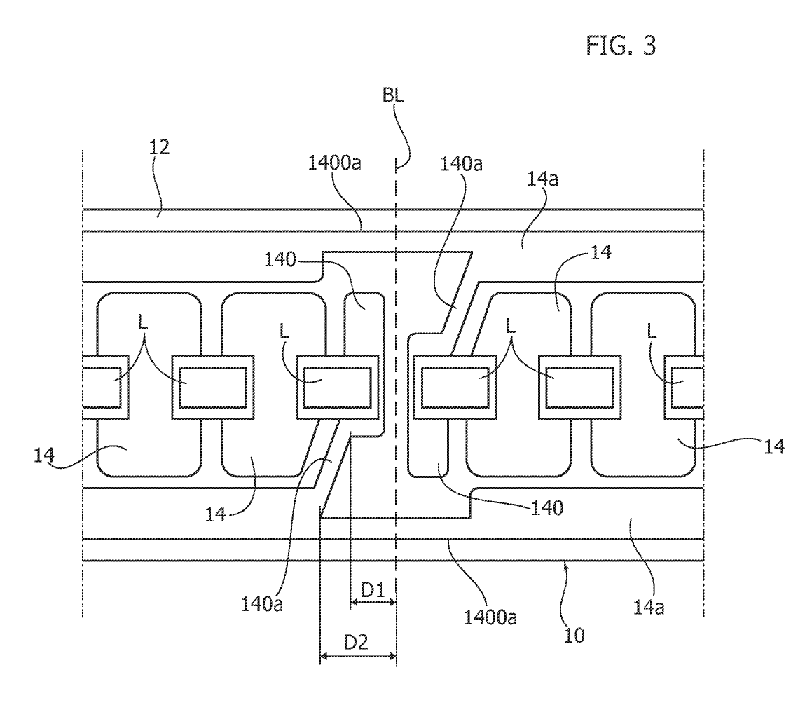

In one or more embodiments, said thermal decoupling provisions may be implemented at the border line BL between adjacent sections . . . Sₙ₋₁, Sₙ, Sₙ₊₁, . . . of printed circuit 10 by changing the shape of electrically conductive lines 14, 14a at the ends of each section S (see e.g. FIG. 2). In one or more embodiments, for example, it is possible to change the shape of the pads which are located adjacent border lines BL. In this way, such “borderline” pads, denoted as 140 in the following, are adapted to have at least one (and optionally every) feature described in the following, which may be inferred e.g. from FIG. 3.

For example, in one or more embodiments, said “borderline” pads 140 may be configured in such a way as to form a separation gap from adjacent border line BL, so that they are at a certain distance to said line. In this way, each borderline pad 140 is spaced from the borderline pad 140 of the adjacent section.

FIG. 3 highlights that, in one or more embodiments, it is possible to avoid the arrangement of any component L bridge-like between adjacent borderline pads 140, as on the contrary may be the case between pads 14 located within one section, or between a borderline pad 140 and the “normal” pad 14 adjacent thereto.

In this way, in one or more embodiments, border lines BL may also define, in a printed circuit 10 of virtually indefinite length, optional partition lines, along which said ribbon-like circuit may be cut so as to originate a sequence of modules, e.g. individual LED lighting modules e.g. of the so-called “flex” type.

In one or more embodiments, borderline pads 140 may be coupled to electrically conductive lines 140a, adapted to act e.g. as electrically conductive bridges towards e.g. either the anode or cathode power lines 14a.

Moreover, the electrically conductive lines 140a are adapted to extend between a first end, located at borderline pad 140, and a second end, located away from borderline pad 140.

In this situation, as exemplified in the bottom part of FIG. 3, the first end of line 140a is at a distance D1 to adjacent border line BL, while said second end is at a second distance D2 to adjacent border line BL, D2 being longer than D1.

In other words, lines 140a may extend distally of the “body” of the respective section of printed circuit 10.

In one or more embodiments, as can be seen e.g. in FIG. 3, conductive lines 140a may extend diagonally or tilted with respect to the general extension direction of printed circuit 10.

In one or more embodiments, borderline pads 140 may be implemented in such a way that two mutually facing borderline pads located on opposed sides of a border line BL are mutually offset transversally of the general extension direction of printed circuit 10.

FIG. 3 also shows that the implementation details of previously exemplified lines 140a (distance D2 longer than distance D1) may enable acting on the thermal path towards (and from) borderline pads 140, e.g. starting from longitudinal lines 14a (which, as shown in FIG. 3, may extend continuously in subsequent sections of printed circuit 10).

In one or more embodiments, said path may be made “longer” than would be the case if distance D1 were equal to D2, i.e. if lines 140a extended orthogonally of the longitudinal direction of printed circuit 10.

Moreover, in one or more embodiments lines 140a may form conductive portions with a narrowed section, i.e. including a line body having a smaller cross-section (area) than the ends of line 140a, which are connected to borderline pad 140 and to the “longitudinal” line or to one of the “longitudinal” lines 14a.

In one or more embodiments, if said longitudinal line(s) 14a extend continuously along printed circuit 10, said longitudinal lines 14a may have narrow-section portions 1400a near border lines BL.

In this way it is possible to reduce the cross section area of the electrically (and thermally) conductive material of said lines 14a.

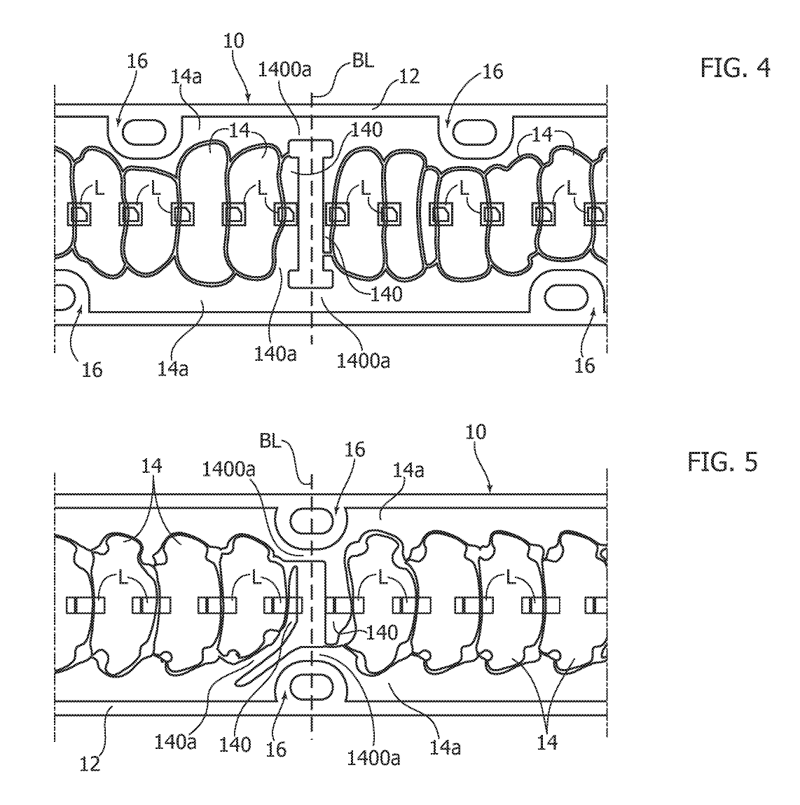

FIGS. 4 and 5 exemplify the possible actual appearance of a printed circuit 10 according to one or more embodiments.

FIGS. 4 and 5 exemplify the possibility of providing substrate 12 with openings (e.g. holes) for fixing printed circuit 10 to a support. This may take place e.g. via screws or pins (not shown in the Figures) which go through such openings, which may correspond to notches 16 in the metal material of the electrically conductive lines (e.g. 14a).

Specifically, FIG. 5 shows, in a comparison with FIG. 4, the possibility of forming such openings (and thus notches 16) exactly at border lines BL, thereby reducing, in the portions denoted as 1400a, the cross section area through which thermal propagation may take place between adjacent sections Sₙ₋₁, Sₙ, Sₙ₊₁, . . . of printed circuit 10.

Of course, without prejudice to the basic principles, the implementation details and the embodiments may vary, even appreciably, with respect to what has been described herein by way of non-limiting example only, without departing from the extent of protection.

While the invention has been particularly shown and described with reference to specific embodiments, it should be understood by those skilled in the art that various changed in form and detail may be made therein without departing from the spirit and scope of the invention as defined by the appended claims. The scope of the invention is thus indicated by the appended claims and all changes which come within the meaning and range of equivalency of the claims are therefore intended to be embraced.

1. A method of countering heat propagation between adjacent sections of a ribbon-like printed circuit board with said sections individually exposed to heat between opposed border lines, wherein said printed circuit board includes an electrically insulating substrate with electrically conductive pads for mounting components thereon,
the method comprising terminating said adjacent sections at said opposed border lines with at least one electrically conductive borderline pad, wherein said at least one borderline pad:
has a separation gap to the border line, and/or
is coupled to an electrically conductive line extending on said substrate between a first end at said at least one borderline pad and a second end away from said at least one borderline pad, said first end and said second end having respective first and second distances to the border line, with said second distance longer than said first distance, and/or
is coupled to an electrically conductive line extending on said substrate between a first end at said at least one borderline pad and a second end away from said at least one borderline pad, wherein said electrically conductive line has a narrower cross section than said first and second ends.

2. The method of claim 1, further comprising providing at the border line between two said adjacent sections of the printed circuit board mutually facing borderline pads of said adjacent sections, wherein said mutually facing borderline pads are offset with respect to each other transversally of the printed circuit board.

3. The method of claim 1, wherein said printed circuit board includes at least one electrically conductive longitudinal line extending lengthwise of said printed circuit board, preferably at a lateral side thereof, over said adjacent portions, said at least one longitudinal line having narrowed portions with a narrowed cross section extending bridge-like across said border lines.

4. The method of claim 1, further comprising providing openings at said border lines between adjacent sections of said printed circuit board, whereby said printed circuit board has a reduced cross section at said border lines.

5. The method of claim 1, including cutting the printed circuit board at said border lines between adjacent sections to produce individual printed circuit modules having said components mounted thereon.

6. A ribbon-like printed circuit board including adjacent sections to be individually exposed to heat between opposed border lines, wherein said printed circuit board comprising an electrically insulating substrate with electrically conductive pads for mounting components thereon, wherein said adjacent sections terminate at said opposed border lines with at least one electrically conductive borderline pad wherein said at least one borderline pad:
has a separation gap to the border line, and/or
is coupled to an electrically conductive line extending on said substrate between a first end at said at least one borderline pad and a second end away from said at least one borderline pad, said first end and said second end having respective first and second distances to the border line, with said second distance longer than said first distance, and/or
is coupled to an electrically conductive line extending on said substrate between a first end at said at least one borderline pad and a second end away from said at least one borderline pad, wherein said electrically conductive line has a narrower cross section than said first and second ends.

7. The printed circuit board of claim 6, further comprising at the border line between two said adjacent sections of the printed circuit board mutually facing borderline pads of said adjacent sections, wherein said mutually facing borderline pads are offset with respect to each other transversally of the printed circuit board.

8. The printed circuit board of claim 6, further comprising at least one electrically conductive longitudinal line extending lengthwise of said printed circuit board, preferably at a lateral side thereof, over said adjacent portions, said at least one longitudinal line having narrowed portions with a narrowed cross section extending bridge-like across said border lines.

9. The printed circuit board of claim 6, further comprising openings at said border lines between adjacent sections of said printed circuit board, whereby said printed circuit board has a reduced cross section at said border lines.

10. The printed circuit board of claim 6, further comprising components, preferably electrically-powered light radiation sources such as LED sources mounted onto said electrically conductive pads.
